(19) United States
(12) Patent Application Publication
(10) Pub. No.: US 2013/0015146 A1
(43) Pub. Date: Jan. 17, 2013

(54) COMPUTER PRIVACY TRAY

(71) Applicant: David IBEAWUCHI, North Hills, CA (US)

(72) Inventor: David IBEAWUCHI, North Hills, CA (US)

(21) Appl. No.: 13/541,924

(22) Filed: Jul. 5, 2012

Related U.S. Application Data
(60) Provisional application No. 61/507,470, filed on Jul. 13, 2011.

(51) Int. Cl. H05K 7/00

(52) U.S. Cl. 211/26

(57) ABSTRACT

A computer privacy device is disclosed that blocks viewing of a laptop display screen by other people from either side of the monitor independently. The device can be used with any portable computer, such as laptops, IPADS, tablets and electronic book readers. A laptop computer is placed upon a support tray that has multiple privacy panels attached to it. The privacy panels are hingedly attached, retractable, or capable of being housed within the support tray. The user simply pivots or extends the privacy panels away from the face of the support tray, places a computer upon the support tray, and adjusts the angle of each privacy panel to achieve the desired privacy. The result is a computer privacy device that is compact, portable, easy to use, and does not require attachment to the computer. The device may further comprise a wrist support.

### CROSS-REFERENCE TO RELATED APPLICATION

This present application claims the priority of Provisional Patent Application No. 61/507,470 filed Jul. 13, 2011. The prior application is incorporated herein by reference

### FEDERALLY SPONSORED RESEARCH

Not Applicable

### SEQUENCE LISTING OR PROGRAM

Not Applicable

### STATEMENT REGARDING COPYRIGHTED MATERIAL

Portions of the disclosure of this patent document contain material that is subject to copyright protection. The copyright owner has no objection to the facsimile reproduction by anyone of the patent document or the patent disclosure as it appears in the Patent and Trademark Office file or records, but otherwise reserves all copyright rights whatsoever.

### BACKGROUND

Computers in the form of laptop models, desktop models, and tablets are an integral part of everyday life and as such are utilized very frequently. Because computers are integrated into our daily activities and have become highly portable, private information is often entered and transmitted using them. The frequent use of computers often occurs in public settings where the user would like to block the information on the computer screen from other people. Because computer screens do not block viewing from the sides of the screen the user must impractically adjust their viewing position to maintain privacy or refrain from using their computer in public.

Information relevant to attempts to address these problems can be found in U.S. Pat. Nos. 7,134,758, 6,765,550 and 7,247,356. However, each of these references suffers from one or more of the following disadvantages: they are cumbersome to transport and assemble; must be attached directly to the computer, making them difficult to secure and remove; and have the potential for causing irreversible damage to the computer.

For the foregoing reasons, there is a need for a computer privacy device that is portable, easy to use, does not require attachment to the computer, and limits viewing of the computer monitor to only the person in from of the laptop display screen.

### SUMMARY

The present invention is directed to a computer privacy device that satisfies the need to maintain private use of a computer by blocking the view of what is on a laptop display screen from others. A computer privacy device having features of the present invention comprises a support tray and privacy panels being attached to the support tray. The privacy panels are attached to the support tray so that they may be pivoted onto or housed within the support tray.

A computer privacy device comprising multiple privacy panels allows the user to block viewing of a laptop display screen from either side of the monitor independently. When not in use, privacy panels that are hingedly attached, retractable, or capable of being housed within the support tray, result in a computer privacy device that is compact and portable, a characteristic highly desirable of electronic accessories.

A laptop can be utilized with the invention in two ways. First, the user can open the privacy panels and place the keyboard portion of the laptop on top of the support tray so that the side privacy panels block viewing of both the screen and the keyboard. Second, a user may rest the support tray of the invention against a wall or slanted surface with the side privacy panels raised to the sides. Here, the screen portion of the laptop rests against the tray and the keyboard portion of the laptop rests on a flat surface like a table. When not in use, the side privacy panels can be lowered so that they rest on top of the tray in a closed position.

There are three embodiments of the present invention. In the first two embodiments, the side panels rest on top of the tray and are foldable. In the first embodiment, the height of each side privacy panel is approximately equal to the one-half the width of the tray. The side privacy panels can both rest against the support tray in the closed position. In a second embodiment, the height of each side privacy panel is substantially equal to the width of the tray. Maximum privacy is afforded because the side panels are long and can best prevent viewing from the periphery. In the second embodiment, the side privacy panels can rest on top of each other in the closed position. In a third embodiment, the side panels are housed inside the support tray in the closed position, and therefore retractable. The side privacy panels can be pulled out of the support tray from the sides and raised for privacy. The side panels can be pulled out and raised at various lengths, meaning that the side privacy panels themselves are foldable.

Because computers are available in various sizes, the computer privacy device may comprise a support tray with an expandable width. The user may then expand the width of the support tray by extending the sides of the support tray outward. Further, the device may comprise privacy panels that have an extendable length to provide an additional range of privacy. Optionally, the device may include a wrist support, for the user's wrists to rest upon, attached to the user-side of the support tray. While the invention is intended to be used with laptop computers, it is understood that any portable computer can be used with the present invention, including IPADS, tablets and electronic book readers.

### DRAWINGS

These and other features, aspects, and advantages of the present invention will become better understood with regard to the following description, appended claims, and accompanying drawings.

FIG. 1 is a perspective view of a device embodying features of the first embodiment of the present invention of a computer privacy device in an open position.

FIG. 2 is a perspective view of the first embodiment of the invention of FIG. 1 in a closed position.

FIG. 3 is a perspective view of a device embodying features of the second embodiment of the present invention of a computer privacy device in an open position.

FIG. 4 is a perspective view of the second embodiment of the invention of FIG. 2 in a closed position.

FIG. 5 is a perspective view of a preferred embodiment of the present invention of a computer privacy device.

FIG. 6 is a perspective view of an alternate embodiment of the present invention of a computer privacy device.

FIG. 7 is a perspective view of another alternate embodiment of the present invention of a computer privacy device.

FIG. 8 is a perspective view of another alternate embodiment of the present invention of a computer privacy device.

The invention does not require that all the advantageous features and all the advantages need to be incorporated into every embodiment of the invention.

### DESCRIPTION

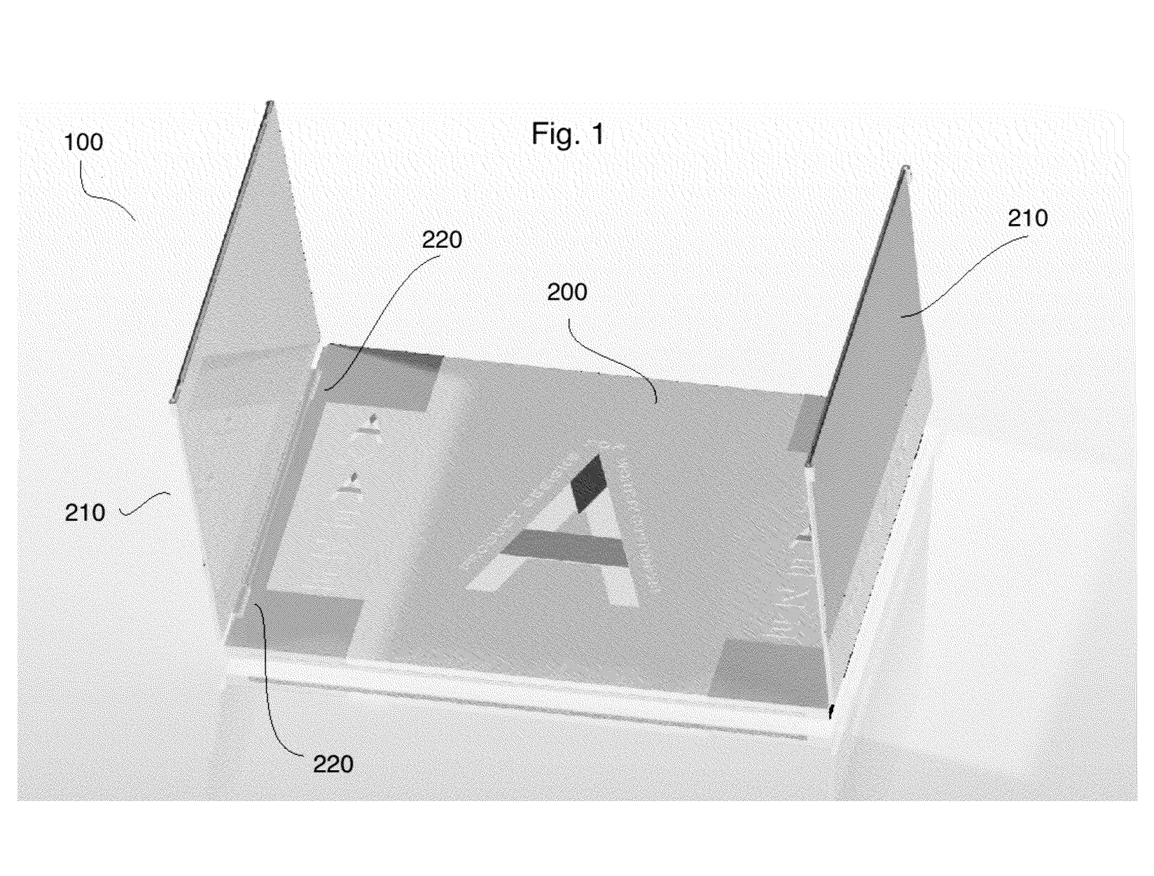

Referring to FIG. 1 a computer privacy device 100 is shown in an open position. The device comprises a support tray 200, a plurality of privacy panels 210, and hinges 220. The support tray 200 allows for the placement of a laptop computer upon its face and serves a mounting place for the privacy panels 210. The privacy panels 210 are connected pivotally to the support tray 200 at their proximal edge by hinges 220. The hinges 210 allow each privacy panel 210 to pivot around their proximal edge. Before placing a laptop on the face of the support tray 200, the device is opened by pivoting the privacy panels 210 away from the face of the support tray 200. In the open position, privacy panels 210 obstruct the line of sight to the laptop display screen by people other than the device user.

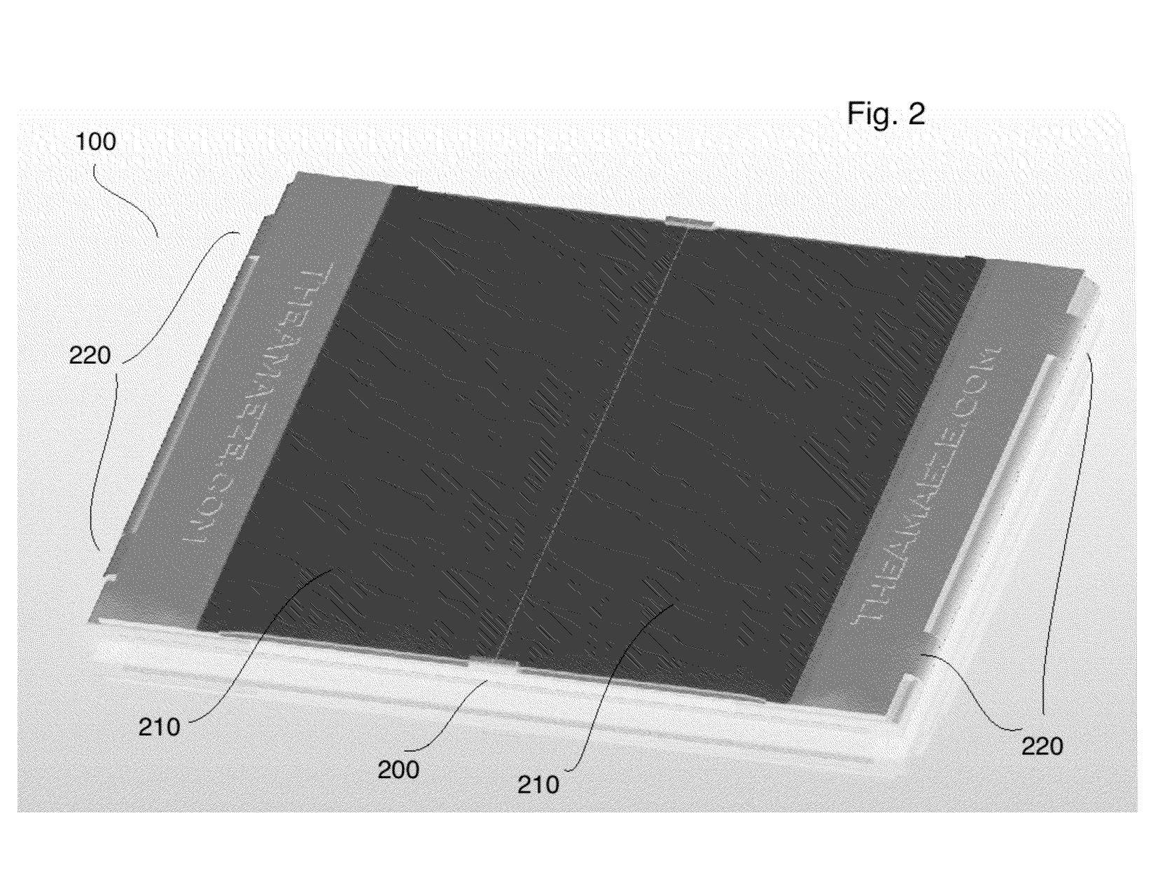

In FIG. 2, the computer privacy device 100 of FIG. 1 is shown with privacy panels 210 in a closed position. In the closed position, the panels pivot toward the face of the support tray 200. In this embodiment, the distal length of the privacy panels 210 is one-half the width of the support tray 200.

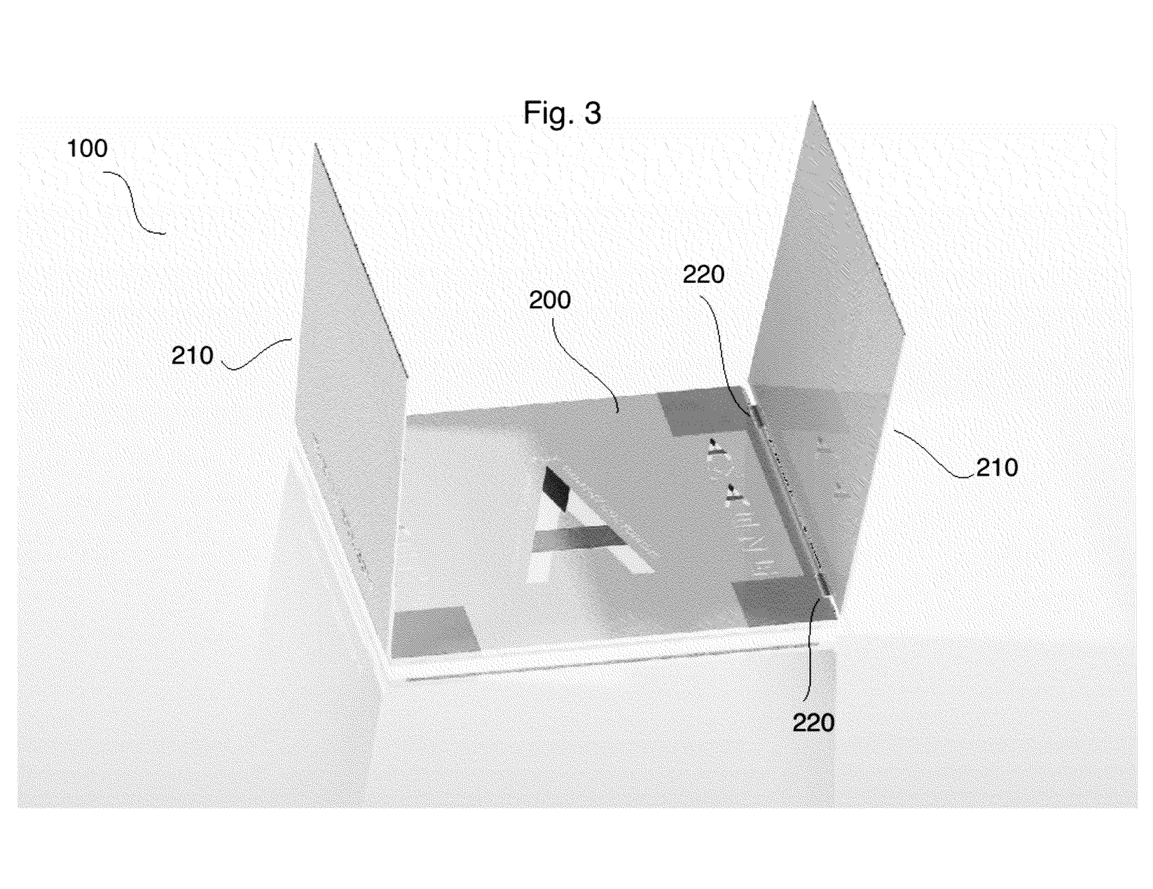

Referring to FIG. 3 a computer privacy device 100 is shown in an open position. In this embodiment, the privacy panels 210 have a distal length greater than one-half the width of the support tray 200, allowing for a greater area of privacy to be achieved when in the open position.

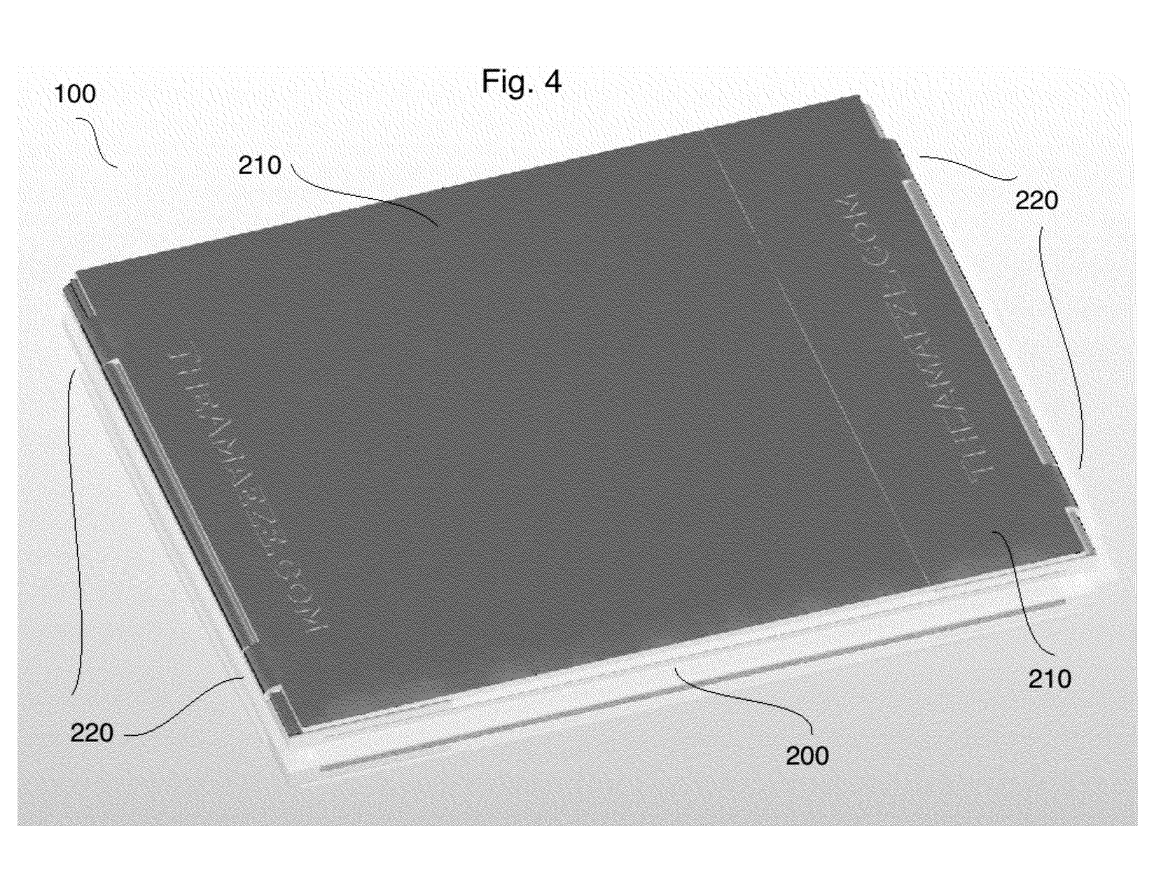

In FIG. 4, the computer privacy device 100 of FIG. 3 is shown with privacy panels 210 in a closed position. In the closed position, the panels pivoted toward the face of the support tray 200 and overlap with each other.

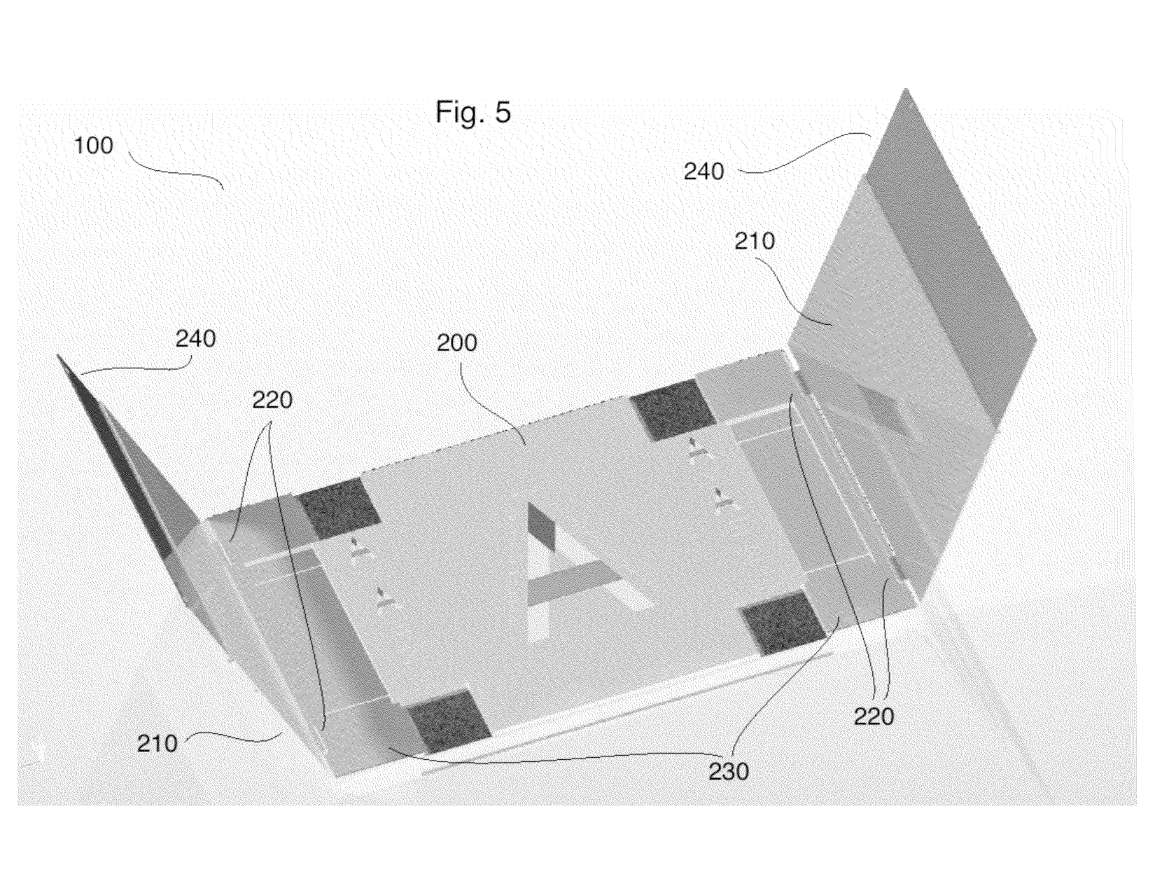

Referring to FIG. 5 a computer privacy device 100 is shown in an open position. This preferred embodiment comprises extendable support tray sections 230 and extendable privacy panel sections 240. The extendable support tray sections 230 increase the width of the support tray 200, allowing for computers of varying size to be placed upon the face of the support tray 200. The extendable privacy panel sections 240 increase in distal length, allowing for a greater area of visibility to be blocked.

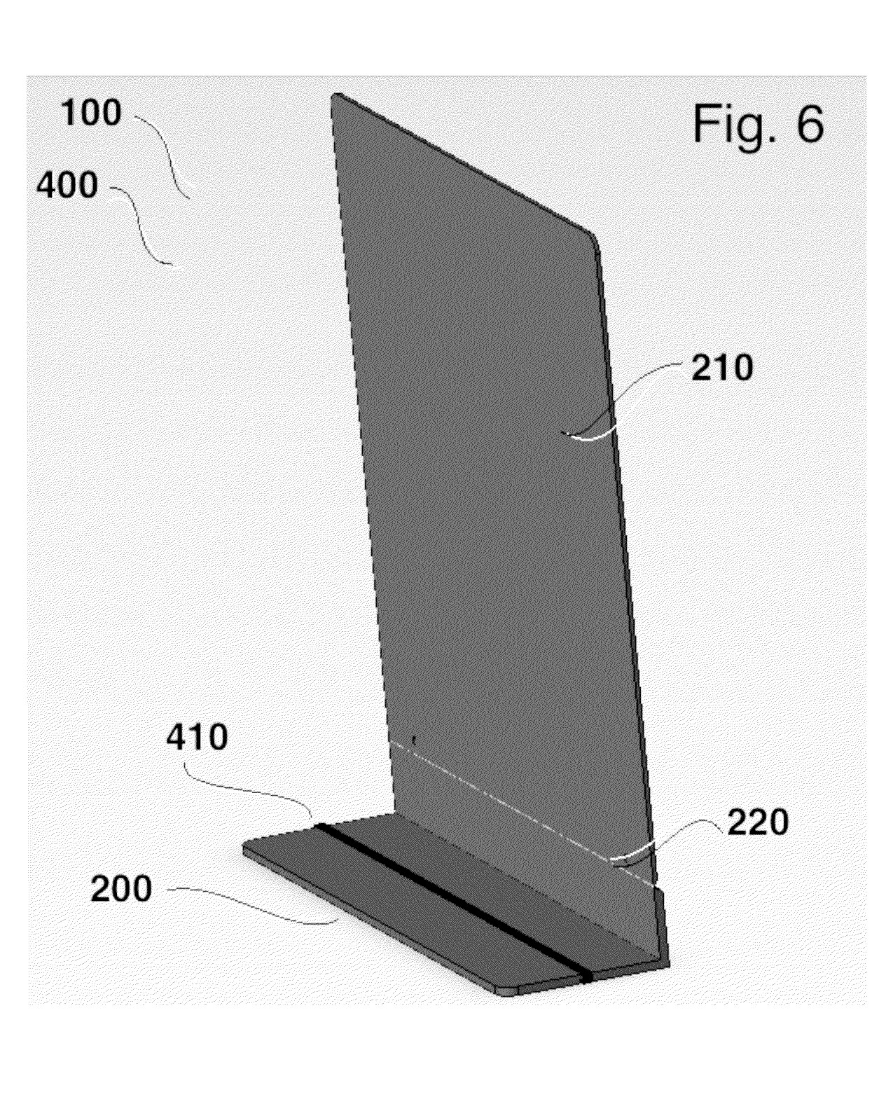

Referring to FIG. 6 a computer privacy device 100 is shown in which the support tray 200 is affixed directly to the computer using securing strap 410. The support tray is placed under side of a computer and affixed using the securing strap 410. The privacy panel 210 is then capable of being pivoted around hinge 220 toward or away from a computer keyboard.

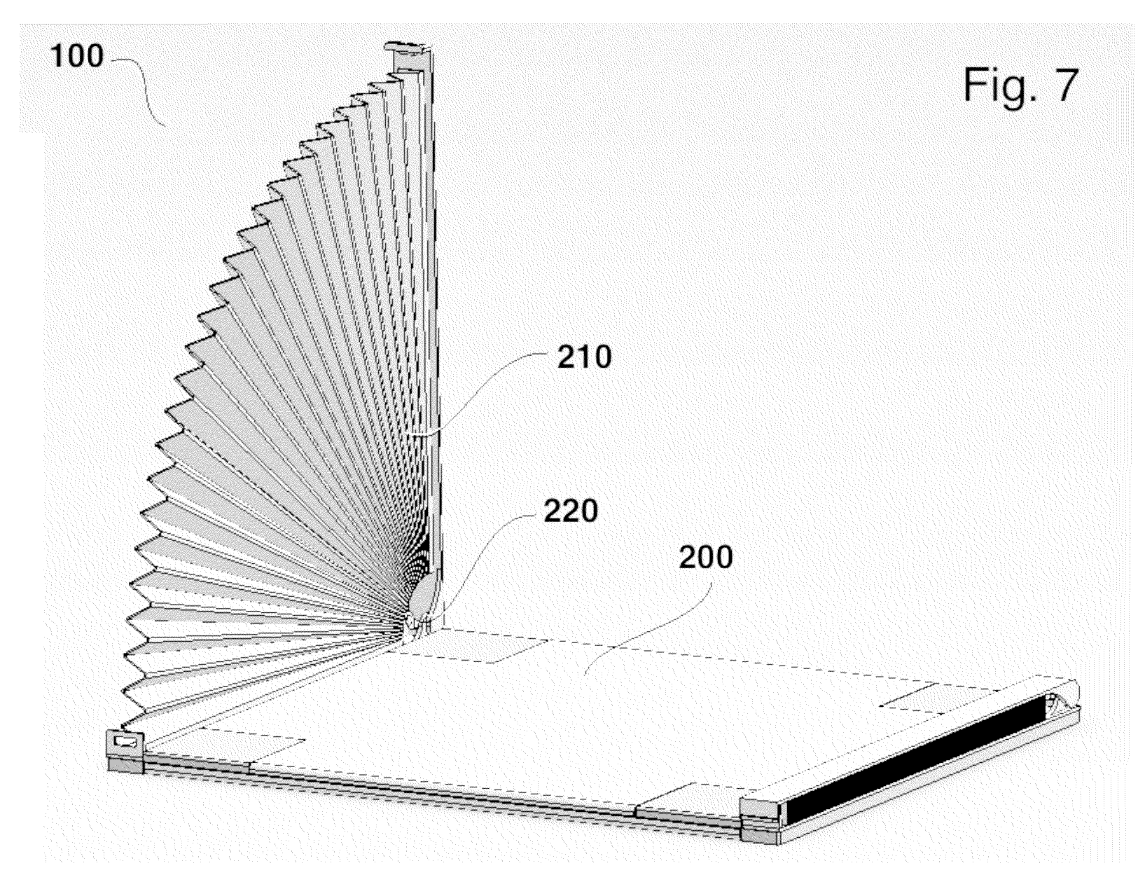

Referring to FIG. 7 a computer privacy device 100 is shown with one privacy panel 210 in the open position. This embodiment comprises a privacy panel 210 that is extendable and pivots around the hinge. The privacy panel 210 can be expanded and retracted in an accordion manner.

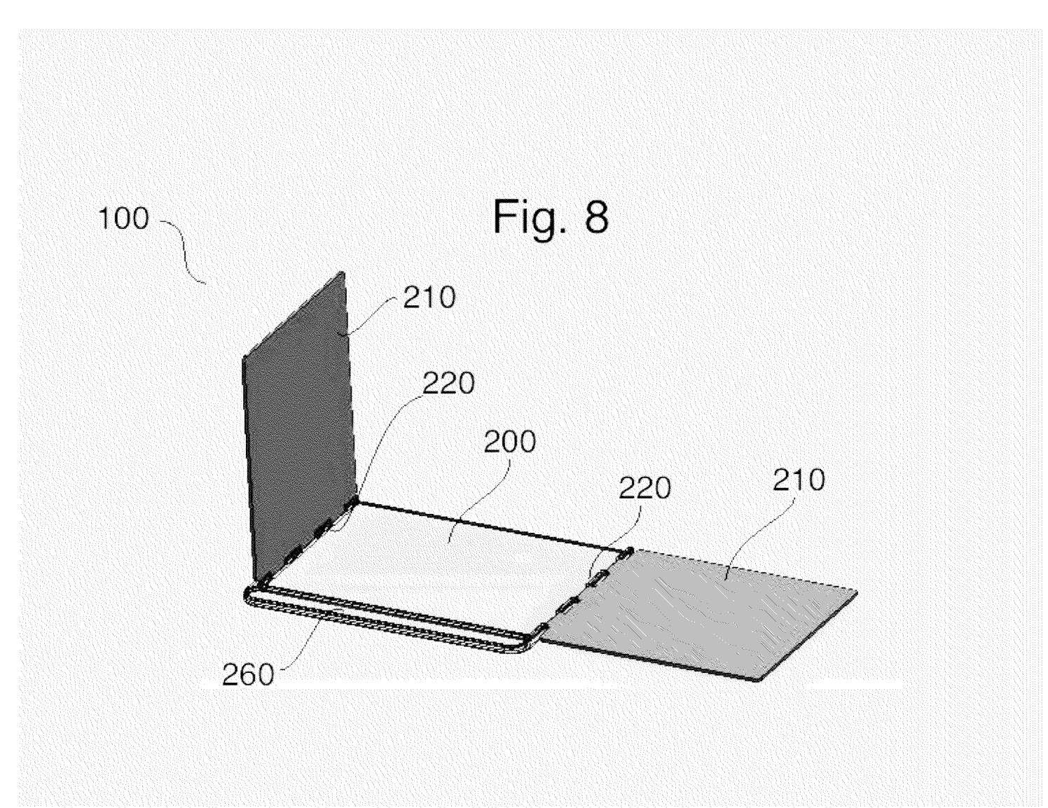

Referring to FIG. 8, a computer privacy device 100 is shown with an optional wrist support 260. The wrist support provides a place for the user to rest their wrists while using the device,

In the embodiments shown in FIGS. 1-7, the computer privacy device 100 may be used in the following manner: first, placing the computer privacy device 100 on a surface or lap of the user; second, pivoting or extending the privacy panels 210 away from the face of the support tray 210; third, expanding the width of the support tray 210 is necessary; fourth, placing a computer on the face of the support tray 210; fifth, expanding the length of the privacy panels 210 if necessary; sixth, adjusting the angle of each privacy panel 210 to achieve the desired privacy.

All features disclosed in this specification, including any accompanying claim, abstract, and drawings, may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, paragraph 6. In particular, the use of “step of” in the claims herein is not intended to invoke the provisions of 35 U.S.C. §112, paragraph 6.

Although preferred embodiments of the present invention have been shown and described, various modifications and substitutions may be made thereto without departing from the spirit and scope of the invention. Accordingly, it is to be understood that the present invention has been described by way of illustration and not limitation.

What is claimed:

1. A computer screen privacy device, the device comprising:
(a) a support tray for placing a portable computer thereupon;
(b) a plurality of privacy panels secured to the support tray for maintaining privacy; and
(c) a plurality of hinges pivotally connecting the plurality of privacy panels to the support tray.

2. The computer screen privacy device of claim 1, wherein the support tray comprises retractable and extendable sections to widen or shorten the width of the support tray.

3. The computer screen privacy device of claim 1, wherein the plurality of privacy panels comprises retractable and extendable sections to lengthen or shorten the height of the privacy panels.

4. The computer screen privacy device of claim 1, wherein the plurality of privacy panel can be expanded and retracted in an accordion manner.

5. The computer screen privacy device of claim 1, further comprising a wrist support.

6. A computer screen privacy device comprised of a support tray affixed directly to a portable computer using securing straps, wherein a portion of the support tray is affixed under the portable computer while the remaining portion of the support tray blocks viewing of the portable computer from a periphery.

7. The computer screen privacy device of claim 6, further comprising a wrist support.

8. The computer screen privacy device of claim 4, wherein the portion of the support tray affixed under the portable computer and the remaining portion of the support tray are joined together by a hinge that pivotally connects both portions.

9. A method of using the computer screen privacy device of claim 1, comprised of the steps of:
placing the computer privacy device on a surface or lap of the user;
pivoting or extending privacy panels away from a face of the support tray;
expanding the width of the support tray, as necessary, to accommodate a portable computer;
placing a computer on the face of the support tray;
expanding the length of the privacy panels, as needed, to block viewing from the periphery of the portable computer; and
adjusting the angle of each privacy panel to achieve the desired privacy.
